(19) United States
(12) Patent Application Publication
(10) Pub. No.: US 2008/0019806 A1
(43) Pub. Date: Jan. 24, 2008

(54) Small footprint modular processing system

(76) Inventors: Nyi Oo Myo, Campbell, CA (US); Steven Poppe, Pleasanton, CA (US); Anthony White, Cupertino, CA (US); Nety M. Krishna, Sunnyvale, CA (US)

Correspondence Address: PATTERSON & SHERIDAN, LLP, 3040 POST OAK BOULEVARD, SUITE 1500, HOUSTON, TX, 77056, US

(21) Appl. No.: 11/491,577

(22) Filed: Jul. 24, 2006

(51) Int. Cl. H01L 21/677

(52) U.S. Cl. 414/217

(57) ABSTRACT

A method and apparatus for a modular processing system is described. The apparatus includes a transfer chamber as the foundation for the system and includes sidewalls adapted to receive at least three 200 mm and/or 300 mm process chambers. The transfer chamber includes a robot capable of withstanding high temperatures and is configured to transfer 200 mm and 300 mm substrates. The modularity of the transfer chamber is highly transportable and provides a research and development platform at a low cost of ownership and may be modularly built into a production system as additional chambers and peripheral hardware is added.

### BACKGROUND OF THE INVENTION

1. Field of the Invention

This invention relates to semiconductor processing equipment. More particularly, the invention relates to a semiconductor processing system having modular capabilities and a small footprint.

2. Description of the Related Art

The semiconductor fabricating field is a highly dynamic industry that continues to meet evolving consumer demands while overcoming tremendous engineering obstacles. While there is a constant drive to make electronic devices smaller than the state of the art, the majority of device manufacturers rely on proven production tools to produce proven and marketable state of the art devices to meet consumer demand at a reasonable profit.

One commonly utilized production tool is a cluster-type tool, which generally includes a plurality of process chambers coupled to a central transfer chamber. Another type of conventional production tool is an in-line system, which generally includes a plurality of linearly arranged process chambers and a transfer device utilized to transfer substrates between the various process chambers. The typical production tool has many large and heavy components, is time consuming to assemble, and generally requires a permanent or semi-permanent space in a clean room as it cannot be moved easily. These tools are typically highly efficient, enabling high throughput and good process repeatability, and this typically results in higher profitability for the manufacturer. The typical production tool also requires a significant capital outlay and any profitability is highly dependent on the tool remaining on-line, with little or no process interruption other than required or scheduled maintenance.

In the quest for smaller device sizes and more efficient manufacturing parameters, a manufacturer may develop a new process or fabrication recipe that will need to be tested prior to release for production. To perform this test, the tool must be taken off-line to test the process sequence or recipe. The tool must be calibrated to test the recipe, process at least one wafer, and be re-calibrated to bring the tool back on-line with normal production. Due to this interruptive testing, which results in extensive downtime and may endure one day or longer, a manufacturer may not be able to absorb the cost of research and development (R&D) with the typical production tool used in this manner. Further, start-ups or other interested parties may be prohibited from R&D due to the high initial capital outlay for the production tool and its required clean room space. Also, a manufacturer may desire to reconfigure the tool, which may be difficult due to the platform arrangement of the typical production tool.

What is needed is a modular tool designed for R&D and start-ups with production potential that requires minimal clean room space and may be easily built or reconfigured according to user desires.

### SUMMARY OF THE INVENTION

Embodiments disclosed herein describe a small footprint modular transfer chamber for transferring substrates, such as semiconductor wafers. The transfer chamber is capable of coupling with a plurality of process chambers that may be a combination of 200 mm and 300 mm process chambers.

In one embodiment, a small footprint transfer chamber is described. The transfer chamber includes a body including an interior volume bounded by at least four sidewalls, a substrate transfer port formed through each of the sidewalls, and a transfer robot positioned within the interior volume, the transfer robot configured to withstand temperatures in excess of 100 degrees C.

In another embodiment, a small footprint transfer chamber is described, which includes at least three sidewalls adapted to couple to a plurality of 200 mm and/or 300 mm process chambers, and a robot having an end effector suitable for transferring 200 mm and 300 mm substrates, wherein the transfer chamber defines a plan area less than about 1000 square inches.

In another embodiment, a small footprint transfer chamber is described, which includes a body including an interior volume bounded by at least three sidewalls adapted to couple to a plurality of 200 mm and/or 300 mm process chambers, a substrate transfer port formed through each of the sidewalls, and a transfer robot positioned within the interior volume, the transfer robot configured to withstand temperatures in excess of 100 degrees C, wherein the robot includes an end effector suitable for transferring 200 mm and 300 mm substrates.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a top view of one embodiment of a transfer chamber.

FIG. 1B is a side view of the transfer chamber of FIG. 1A.

FIG. 1C is a schematic top view of one embodiment of a robot.

FIG. 1D is a schematic top view of another embodiment of the robot shown in FIG. 1C.

FIG. 2 is an exploded isometric view of another embodiment of a transfer chamber.

FIG. 3 is a schematic view of one embodiment of a modular processing system.

FIG. 4 is a schematic view of another embodiment of a modular processing system.

FIG. 5 is an isometric view of another embodiment of a processing system.

To facilitate understanding, identical reference numerals have been used, where possible, to designate identical elements that are common to the figures. It is also contemplated that elements disclosed in one embodiment may be beneficially utilized on other embodiments without specific recitation.

### DETAILED DESCRIPTION

Embodiments of the invention provide a transfer chamber that allows users, such as manufacturers or researchers, among others, to build a processing system that is highly modular, thus allowing the manufacturer or researcher to purchase processing equipment on an as-needed basis to build a production system without a significant capital expenditure. The transfer chamber and the modularity of the processing system also allows users to build the system to any desired configuration or reconfigure the processing system as the need arises.

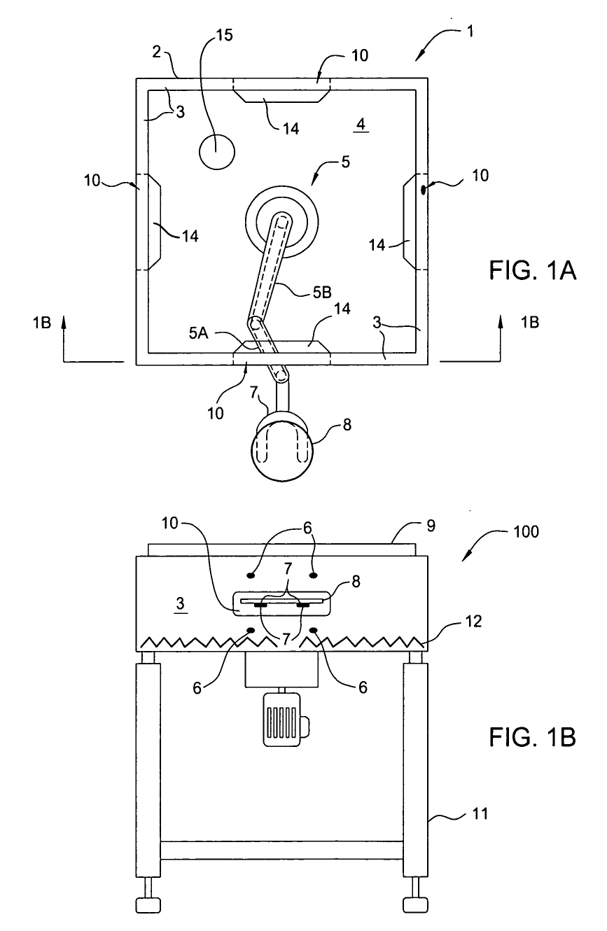

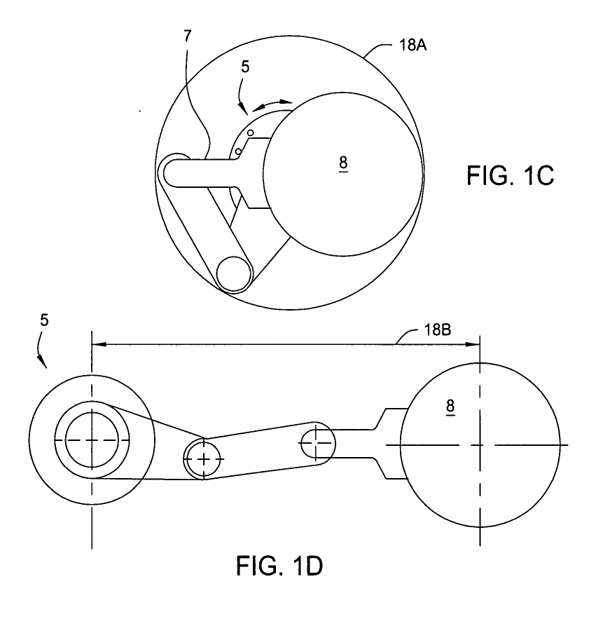

FIG. 1A is a top view of one embodiment of a transfer chamber 100 that, in one embodiment, forms the foundation of a modular processing system. The transfer chamber 100 includes a body 2 bounded by sidewalls 3. A transfer robot 5 is disposed in an interior volume 4 of the body 2. The transfer robot 5 is located at substantially a center-line of the transfer chamber 100. The transfer robot 5 includes at least one end effector 7 configured to support and transport a substrate 8, which may be a 200 mm or 300 mm semiconductor wafer, into and out of substrate transfer ports 10 formed in the sidewalls 3 of the chamber 100.

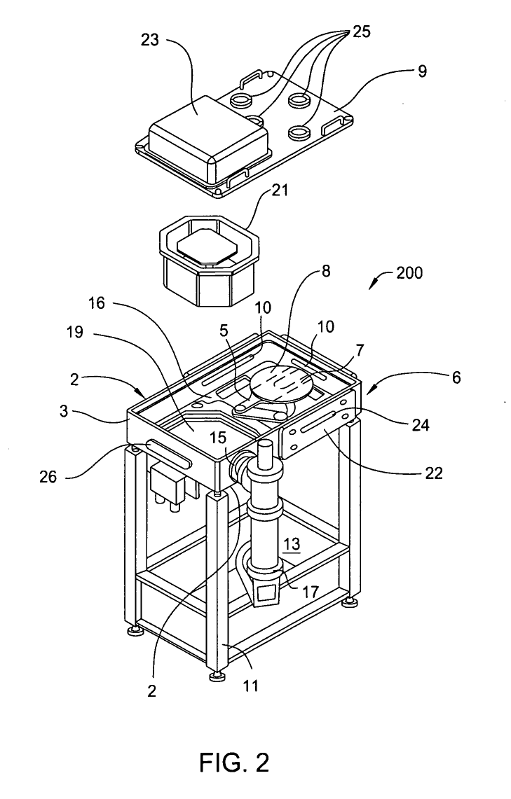

In one embodiment, the transfer chamber 100 is rectangular and each sidewall 3 includes a substrate transfer port 10 having an opening sized to allow passage of a 300 mm substrate. Each substrate transfer port 10 includes valves 14 that are adapted to maintain negative pressure within the transfer chamber 100. The valves 14 may be coupled to the chamber 100 within the interior volume 4 as shown, or may be coupled to the chamber 100 on the exterior of the sidewalls 3. The valves 14 are configured to selectively seal the interior volume 4 of the transfer chamber 100 and allow coupling of a process chamber (not shown) with the transfer chamber 100. The transfer chamber 100 may further include a port 15 for coupling to a source of negative pressure, such as a vacuum pump (not shown). The port 15 may be coupled to the bottom of the transfer chamber 100 as shown, or may be coupled to another portion of the body 2, such as a sidewall 3 as shown in FIG. 2.

FIG. 1B is a side view of the transfer chamber 100 shown in FIG. 1A. A lid 9 is shown covering an upper surface of the transfer chamber 100, and a main frame 11 supports the chamber from the bottom. The lid 9 is removable to provide access to the robot 5 and other portions of the interior volume 4 of the transfer chamber 100 for maintenance and inspection. The lid 9 and body 2 are sealed by an O-ring or gasket disposed between the lid and the upper surface of the transfer chamber 100. The transfer chamber 100 may be fabricated from process resistant materials such as metals, for example aluminum, stainless steel, or alloys thereof. The transfer chamber 100 may also be made of process resistant plastics or ceramic materials having the structural integrity to withstand and maintain negative pressure within the transfer chamber 100. The transfer chamber 100 may be formed from a solid piece of material by machining, or formed from a plurality of machined pieces and joined, such as by welding.

In one embodiment, the robot 5 is adapted for high heat operation within the interior volume 4. For example, the transfer robot 5 is configured to withstand temperatures greater than about 80 degrees C., for example, greater than about 100 degrees C., such as between about 120 degrees C. to about 150 degrees C. The high temperature capability is provided by temperature resistant parts, such as metal belts 5B, which control the articulation of the robots arms and/or end effector. The metal belts 5B replace traditional belt material used in conventional designs to facilitate high-heat operation.

In this embodiment, the transfer chamber 100 may further include a heat source 12, such as a resistive heater, lamps, fluid conduits, and/or heating tape, coupled thereto or formed within the sidewalls 3 or other portions of the chamber 100 to preheat or post-heat the substrate within the interior volume 4 of the transfer chamber 100.

The transfer robot 5 is configured to facilitate transfer of the substrate 8 into, out of, and within the interior volume 4. In one embodiment, the transfer robot 5 is adapted to transfer both 200 mm and 300 mm substrates without significant adjustments to the configuration and movement paradigms of the transfer robot 5. For example, the end effectors 7 may be designed to support 200 mm and 300 mm substrates without the need to replace the end effectors or adjust the end effector length. The inventors adapted the arm 5A and end effector 7 of the transfer robot 5 to extend through the substrate transfer ports 10 and the valves 14 to allow additional extension of the robot 5. For example, the length of the end effector 7 is such that additional extension is realized. Also, the thickness of the arm 5A has been adjusted to provide additional extension of the robot 5, wherein the arm 5A is configured to extend at least partially through the substrate transfer ports 10. In this manner, the robot has a sufficient extended length to transfer 200 mm substrates, as well as 300 mm substrates with only a differing position of the substrate on the end effector. For example, a 300 mm substrate may occupy one area of the end effector, and a 200 mm substrate will occupy a lesser area of the end effector. To facilitate the dual dimensions, the end effector 7 may include arcuate recesses at one or both ends of the end effector, and these recesses are adapted for each substrate diameter.

The transfer chamber 100 is configured to occupy a small foot print, is lightweight, and is proportioned to facilitate mobility throughout a clean room without the use of heavy lifting equipment such as cranes, jacks, skates, fork lifts, and the like, which are typically needed to move conventional transfer chambers. As an example of size, the transfer chamber 100 and 200 of FIGS. 1A and 2, has a width of about 25 inches (63.5 cm), which allows the transfer chamber to be easily moved into a manufacturing facility, and through personnel doors throughout a clean room. The transfer chamber 100, as well as other components, may be delivered to the facility in a clean room package and brought into the facility through personnel pass-throughs, such as air showers and other standard personnel doors, in the facility. In one embodiment, the transfer chambers 100, 200 have a plan area, defined by the area or dimensions, such as width and length of the body 2, as viewed from above, wherein the plan area has at least one dimension that is less than the width of a standard personnel door in a manufacturing facility. Conventional personnel pass-throughs may typically be between about 36 inches (91.44 cm) wide, and the width of the transfer chambers are sized to easily pass therethrough. This is beneficial as conventional transfer chambers have a short side dimension greater than 36 inches (91.44 cm), and thereby cannot enter the clean room through personnel doors. Depending on the facility, this larger size may require entry into the facility through equipment doors, which may result in a significant disruption of the facility along with the time and personnel required to move the equipment through the doors into the clean room.

The transfer chamber 100 is also lightweight when compared to conventional transfer chambers. As an example, the transfer chamber 100, made of an aluminum material, weighs less than about 100 lbs (45.4 kg), such as less than about 90 lbs (40.8 kg), without the robot 5 and other peripheral equipment. This light weight promotes mobility by allowing a user to transport the transfer chamber in and around the facility by hand or by using light-duty moving equipment. This is beneficial as the clean room typically includes light-duty moving equipment within the clean room, such as dollies. As a comparison, a typical conventional transfer chamber may weigh no less than between about 250 lbs (113.4) and 600 lbs (272.1 kg), such as about 200 lbs (90.1 kg), thus requiring medium to heavy duty lifting equipment that may not be readily available to the clean room. In this case, the heavier duty equipment must be wiped-down prior to entering the clean room. This results in disruptions in production due to the reduced mobility of the medium to heavy-duty lifting equipment.

The transfer chamber 100 is also configured to provide a minimal foot print, thus conserving valuable square footage or facilitating use of unused square footage within the facility. For example, the transfer chamber has a plan area less than about 1200 square inches (30.48 square meters), for example about 1000 square inches (25.4 square meters) to about 600 square inches (15.2 square meters), such as about 625 square inches (15.8 square meters) for the transfer chamber 100 shown in FIG. 1A, while the transfer chamber 200 shown in FIG. 2 has an area of about 925 square inches (23.5 square meters). To facilitate this small area, the inventors designed the robot 5 to transfer the substrate in the interior volume 4 in a minimal sweep diameter when retracted.

FIG. 1C is a schematic top view of one embodiment of a robot 5. The robot includes an end effector 7 having a substrate 8 thereon, which in this example is a 300 mm semiconductor wafer. The robot 5 is in a retracted position and comprises a first transfer dimension 18A in this retracted position. In this embodiment, the first transfer dimension is a sweep area, shown as a circle, which is less than about 20 inches (50.8 cm), such as about 19 inches (48.3 cm). The robot 5 is adapted to rotate about an axis wherein no portion of the robot 5 or substrate 8 is outside of the first transfer dimension. The interior volume 4 of the chamber 100 is minimally proportioned to house the robot 5 and allow unimpeded access through each of the substrate transfer ports 10, and facilitate unimpeded movement of the substrate 8 within the interior volume 4. This small area of the interior volume 4, in turn, facilitates the small footprint of the transfer chamber 100.

FIG. 1D is a schematic top view of another embodiment of the robot 5 shown in FIG. 1C. The robot 5 also includes a second transfer dimension 18B, which is an extended position. In this embodiment, the extended position (center of rotational axis of robot to center of 300 mm substrate) is between about 700 mm to about 760 mm, for example about 720 mm. In this embodiment, the robot 5 has a minimal first transfer dimension to enable the small footprint for transfer within the transfer chamber 100, and a second transfer dimension to facilitate transfer of substrates 8 into, out of, the transfer chamber 100.

The transfer chamber 100 is configured to form the center of a processing system by providing access and/or a mating connection for a plurality of 200 mm and/or 300 mm process chambers, such as chemical vapor deposition (CVD) chambers, physical vapor deposition (PVD) chambers, plating chambers, atomic layer deposition (ALD) chambers, etch chambers, heat treating chambers, and the like (not shown). The transfer chamber 100 is also configured to couple to peripheral front end modules, such as a load lock chamber, a load/unload module, a wafer cassette assembly, a transfer module, and the like (also not shown). In one embodiment, at least one sidewall 3 is not coupled to a process chamber or front end module so that its substrate transfer port 10 may allow manual loading and unloading of a single substrate 8 directly from a user in the clean room.

To facilitate coupling to the process chambers and the front end modules, each of the sidewalls 3 may include an interface 6 that accommodates mating of the individual chamber or module to the transfer chamber 100. The interface 6 may include at least one of a plurality of holes, clamps, a plurality of threaded holes, or a plurality of studs or bolts, or locating pins, adjacent each substrate transfer port 10. In one embodiment, the interface 6 includes a plurality of indexing pins and a bolt pattern of threaded holes to receive one of a process chamber or a front end module to facilitate coupling to the transfer chamber 100. In another embodiment, the interface 6 may include an adapter plate 22 (FIG. 2) configured couple to the sidewall 3 and the respective interface 6. The adapter plate 22 includes an aperture 24 sized to allow transfer of a 200 mm substrate and provides a smaller interface suitable for coupling a 200 mm chamber or module to the transfer chamber 100. As described above, the arm 5A (FIG. 1A) and end effector 7 of the transfer robot 5 is adapted to extend through the substrate transfer ports 10, the valves 14, and the adapter plate 22 to allow additional extension of the robot 5. The various chambers and modules are sealed with the transfer chamber 100 by O-rings or any other sealing method to prevent vacuum leakage.

FIG. 2 is an exploded isometric view of another embodiment of a transfer chamber 200. The transfer chamber 200 is similar to the transfer chamber 100 shown in FIGS. 1A, 1B, and like reference numerals are included to denote similar elements. The transfer chamber 200 in this embodiment includes a depression 19 formed in a lower surface 16 of the transfer chamber 200. The depression 19 is configured to receive an elevator assembly 21 adapted to facilitate transfer of substrates. In one embodiment, the depression 19 is a recess formed in the lower surface 16 sized to receive the elevator assembly 21. In another embodiment, the depression 19 is an opening formed through the lower surface 16 sized to receive the elevator assembly 21, wherein a portion of the elevator assembly 21 is adapted to seal the depression 19. The elevator assembly 21 is a removable assembly configured to support a plurality of substrates. In one embodiment, the elevator assembly 21 comprises a wafer cassette, and a vertical drive is coupled to the cassette in a manner that the cassettes' elevation within the transfer chamber is controlled. The vertical drive is configured to move the cassette in a vertical direction, thus selectively aligning each substrate disposed in the cassette with respect to the transfer plane of the robot 5. In this manner, a substrate may be provided by the elevator assembly 21 and returned to the elevator assembly after processing. When the substrate has been returned to the elevator assembly 21, the elevator assembly may be actuated upward or downward to align the next substrate in the queue with the robot 5, and the queued substrate may be processed similarly and returned to the elevator assembly 21.

The lid 9 includes a cover 23 sized to house an upper portion of the elevator assembly 21 and in one embodiment, includes at least one view port 25 to monitor the interior volume 4. In this embodiment, a vacuum pump 17 is shown coupled to the port 15 and the mainframe 11. A tray 13 is coupled to the mainframe 11 below the transfer chamber 200 and may be used to support system controllers that control transfer sequences, a pneumatic device, such as a pneumatic controller, and a compressed air supply used by the transfer chamber 200 or other modules coupled thereto. The transfer chamber 200 also includes at least one external valve 26 to facilitate substrate transfer into the chamber 200 or elevator assembly 21 from the exterior of the chamber 200.

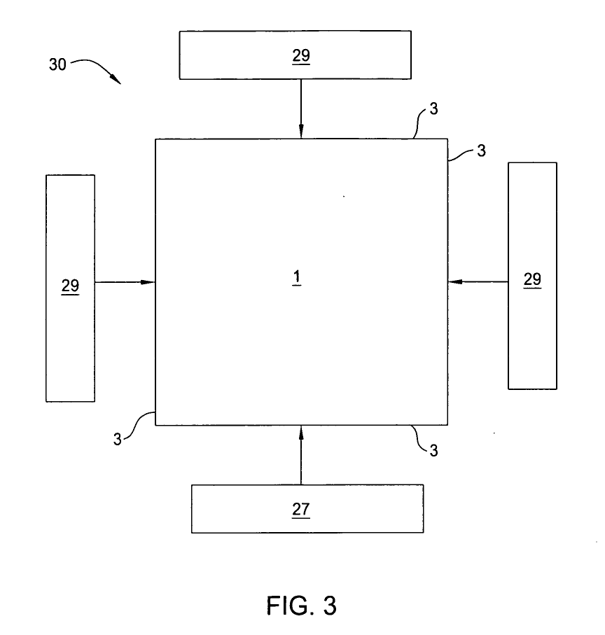

FIG. 3 is a schematic view of one embodiment of a modular processing system 30. The modular processing system 30 includes a transfer chamber 1, which may be the transfer chamber 100 or 200 as described above, or other suitable transfer chamber, having a plurality of process chambers 29 coupled to the sidewalls 3 of the transfer chamber 1. At least one of the sidewalls 3 is adapted to couple to a front end module 27 such as a load lock chamber, a load/unload module, a wafer cassette assembly, a transfer module, and the like. The process chambers 29 may be an assortment of process chambers available from Applied Materials, Inc. of Santa Clara, Calif. Some examples of process chambers 29 may be ALD chambers, CVD chambers, PVD chambers, and the like. Examples of front end modules 27 include single wafer load lock chambers and dual single wafer load lock chambers available from Applied Materials, Inc. It is also contemplated that the transfer chamber 1 may be configured to couple to process chambers and front end modules from other manufacturers.

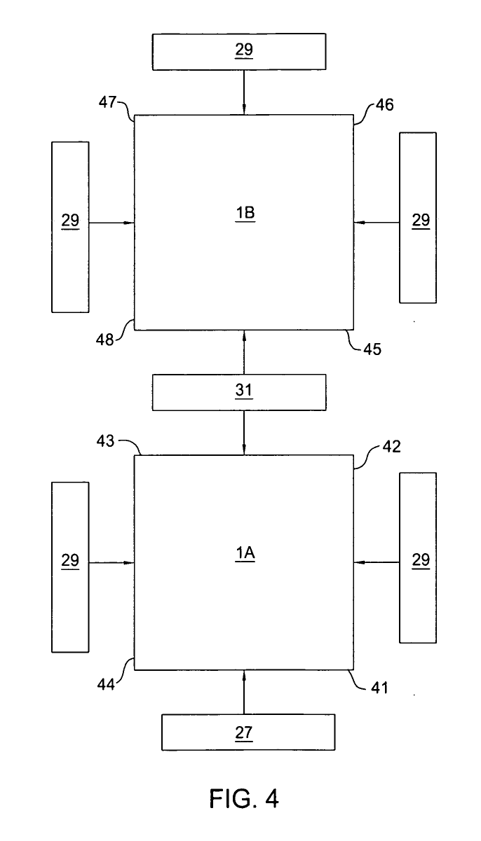

FIG. 4 is a schematic view of another embodiment of a modular processing system 40. The modular processing system 40 includes a first transfer chamber 1A having a front end module 27 coupled to sidewall 41 to provide substrates (not shown) to the transfer chamber 1A. A substrate may be transferred to process chambers 29 coupled to sidewalls 42 and 44 or may be transferred to a transfer module 31 coupled to sidewall 43. The transfer module 31 is coupled to sidewall 45 of a second transfer chamber 1 B which facilitates transfer between the transfer chambers 1A and 1B. The transfer module 31 includes a substrate support and/or lift pins suitable for facilitating handoff between robots in the adjacent transfer chambers 1A, 1B.

In the embodiment depicted in FIG. 4, the transfer module 31 includes a substrate support (not shown) having a plurality of pins extending upward. The plurality of pins define a substantially planar and horizontal support surface for supporting a substrate and are spaced to allow the end effector of the robot to be inserted between the pins. Once the substrate has been transferred to the transfer module 31, the substrate may be transferred to a plurality of process chambers 29 coupled to sidewalls 46-48. The substrate may be processed in this travel route in one or a plurality of chambers 29 coupled to the first and second transfer chambers 1A and 1B, and return to the front end module 27 through the transfer module 31. Alternatively, any one of the plurality of process chambers 29 coupled to the second transfer chamber 1B may be replaced with a front end module 27 (not shown).

In one embodiment, the transfer module 31 is configured to enable a staged vacuum between transfer chambers 1A and 1B. For example, transfer chamber 1A may be pumped down to a pressure of about 10⁻⁵ Torr (133.3 mPa) and the transfer chamber 1B may be pumped to a pressure of about 10⁻⁸ Torr (1.33 pPa).

As has been shown, the transfer chambers 100 and 200 and the processing chamber configurations shown in FIGS. 3 and 4, provide adaptation for many different system layouts as determined by the geometry of the clean room or by user preference. The compact, lightweight design and modularity provided by the transfer chambers described herein provide unlimited portability of a processing system. Once a space or site within the facility has been chosen, plumbing, electrical, and the like, may be provided to the site from central facility sources (if needed), and the transfer chamber may be brought into the facility without the use of heavy lifting devices as described above. The robot, and other peripheral parts, may be brought into the facility and assembled at the site and coupled to the plumbing and electrical. One or more process chambers, and/or a front end device, may be brought into the facility and coupled to the transfer chamber and plumbing to define a processing system having one or more processing chambers. The resulting processing system described above requires minimal capital outlay and minimal to no disruption of the facility. The processing system may then be calibrated, and a process may then be run in the system without the need to take a production tool off-line.

As an example, a user may build a small R&D processing system in an unused corner of a clean room by purchasing the transfer chamber and at least one process chamber 29, and after plumbing, the user may begin running processes using hand loaded substrates placed on the end effector 7 by the user. The user may then want to expand by purchasing another one or more process chambers 29, which may require a second or third transfer chamber. The R&D system may now be a full production tool within the corner of the clean room defining a straight line as shown in FIG. 4 (with two transfer chambers 1A, 1B), or the geometry of the clean room may require a 90 degree turn to make an L shaped processing system in the case of more than two transfer chambers (not shown). In this example, process chamber 29 on sidewall 45 or sidewall 48 may be replaced with a transfer module 31 to facilitate transfer between transfer chamber 1B and the third transfer chamber (not shown). Additionally, the user may combine additional transfer modules 31 and additional transfer chambers for adding more process chambers 29.

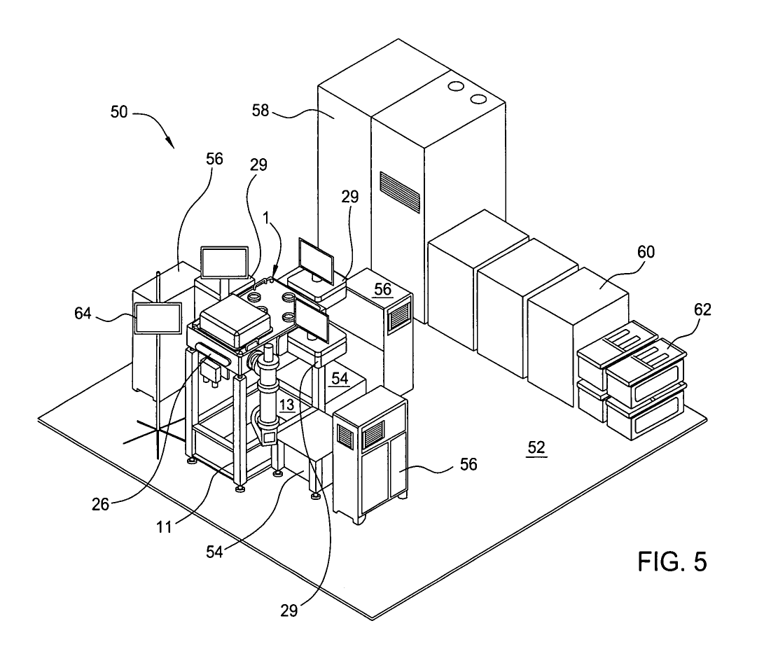

FIG. 5 is an isometric view of another embodiment of a processing system 50 above a clean room floor 52. The processing system 50 includes a transfer chamber 1, which is transfer chamber 200 as shown in FIG. 2. The transfer chamber 1, supported by the mainframe 11, is shown coupled to three process chambers 29. System boxes 54, if necessary or preferred for the process chambers 29, may be positioned below the respective process chamber 29 in order to make the processing system more compact. The system boxes 54 may include process controllers such as pneumatic devices, and gas valving and controls for a process chamber. Dedicated gas boxes 56, for supplying processing materials such as gasses and chemicals, may be dollied and positioned adjacent the transfer chamber 1 if processing materials are not supplied and plumbed from central facility sources through the clean room floor 52. Power to run the processing system 50 may be provided by any power supply available, such as a remote power box 58. Each process chamber 29 may receive temperature controlled water from a dedicated heat exchanger 60. Exhaust may be individually plumbed to specific abatement systems and the roughing is provided by exhaust pumps 62. High level control of the transfer chamber 1 and the processing system is provided by a computer 64 having a touch screen monitor adjacent the transfer chamber 1.

While the foregoing is directed to embodiments of the present invention, other and further embodiments of the invention may be devised without departing from the basic scope thereof, and the scope thereof is determined by the claims that follow.

1. A transfer chamber, comprising:
a body including an interior volume bounded by at least four sidewalls;
a substrate transfer port formed through each of the sidewalls; and
a transfer robot positioned within the interior volume, the transfer robot configured to withstand temperatures in excess of 100 degrees C.

2. The transfer chamber of claim 1, wherein at least three of the substrate transfer ports include a valve positioned in the interior volume.

3. The transfer chamber of claim 1, wherein each substrate transfer port is sized to pass a 300 mm substrate therethrough.

4. The transfer chamber of claim 3, further comprising:
an adapter coupled over an opening of at least one of the substrate transfer ports, the adapter reducing the opening and having an aperture sized to pass a 200 mm substrate therethrough.

5. The transfer chamber of claim 1, wherein the body has a width sized to pass through a standard personnel door in a clean room.

6. The transfer chamber of claim 1, wherein the transfer robot further comprises:
an arm and coupled with an end effector, wherein the arm and end effector are sized to pass at least partially through the substrate transfer port when the transfer robot is in an extended position.

7. The transfer chamber of claim 1, wherein at least one of the sidewalls includes an interface adapted to facilitate coupling to one of a load lock chamber, a process chamber, or a wafer cassette assembly.

8. The transfer chamber of claim 1, wherein the transfer chamber comprises a plan area of less than about 1000 square inches.

9. The transfer chamber of claim 1, wherein the transfer chamber is adapted for manual substrate transfer from outside of the body.

10. The transfer chamber of claim 1, wherein the robot has at least one arm configured to at least partially pass through each substrate transfer port.

11. The transfer chamber of claim 1, wherein the interior volume further comprises:
a depression; and
an elevator assembly disposed in the depression and configured to control an elevation of a substrate storage cassette within the body.

12. The transfer chamber of claim 1, further comprising:
a heater disposed within the body.

13. The transfer chamber of claim 1, further comprising:
a lid coupled with the body, the lid having a plurality of view ports.

14. A transfer chamber, comprising:
at least three sidewalls adapted to couple to a plurality of 200 mm and/or 300 mm process chambers; and
a robot having an end effector suitable for transferring 200 mm and 300 mm substrates, wherein the transfer chamber defines a plan area less than about 1000 square inches.

15. The transfer chamber of claim 14, wherein the robot is adapted to withstand a temperature in excess of 100 degrees C.

16. The transfer chamber of claim 14, wherein the robot includes metal belts that facilitate movement of the end effector.

17. The transfer chamber of claim 14, wherein the transfer chamber comprises a weight of less than about 90 lbs.

18. The transfer chamber of claim 14, wherein the robot further comprises:
an arm and coupled with the end effector, wherein the arm and end effector are sized to pass at least partially through the substrate transfer port when the transfer robot is in an extended position.

19. The transfer chamber of claim 14, further comprising:
an interior volume;
a depression within the interior volume; and
an elevator assembly disposed in the depression and configured to control an elevation of a substrate storage cassette within the interior volume.

20. A transfer chamber, comprising:
a body including an interior volume bounded by at least three sidewalls adapted to couple to a plurality of 200 mm and/or 300 mm process chambers;
a substrate transfer port formed through each of the sidewalls; and
a transfer robot positioned within the interior volume, the transfer robot configured to withstand temperatures in excess of 100 degrees C., wherein the robot includes an end effector suitable for transferring 200 mm and 300 mm substrates.

21. The transfer chamber of claim 20, wherein the body defines a plan area less than about 1000 square inches.

22. The transfer chamber of claim 20, wherein the interior volume includes a depression and an elevator assembly is disposed in the depression and is configured to control an elevation of a substrate storage cassette within the interior volume.

23. The transfer chamber of claim 20, wherein the robot further comprises:
an arm and coupled with the end effector, wherein the arm and end effector are sized to pass at least partially through each substrate transfer port when the transfer robot is in an extended position.

24. The transfer chamber of claim 20, wherein at least one of the sidewalls includes an interface adapted to facilitate coupling to one of a load lock chamber, a process chamber, or a wafer cassette assembly.

25. The transfer chamber of claim 20, further comprising:
an adapter coupled over an opening of at least one of the substrate transfer ports formed in the sidewalls, the adapter reducing the opening and having an aperture sized to pass a 200 mm substrate therethrough.

26. The transfer chamber of claim 25, wherein the robot further comprises:
an arm and coupled with the end effector, wherein the arm and end effector are sized to pass at least partially through the adapter when the transfer robot is in an extended position.
